(19) United States
(12) Patent Application Publication
(10) Pub. No.: US 2016/0071993 A1
(43) Pub. Date: Mar. 10, 2016

(54) SOLAR ENERGY COLLECTION DEVICE

(71) Applicant: Scott A. McLain, La Porte, IN (US)

(72) Inventor: Scott A. McLain, La Porte, IN (US)

(21) Appl. No.: 14/478,146

(22) Filed: Sep. 5, 2014

(51) Int. Cl. H01L 31/052

(52) U.S. Cl. CPC H01L 31/0524

(57) ABSTRACT

A solar energy collection device efficiently focuses and collects solar energy. The device includes a frame and a lens coupled to the frame such that the frame extends around the lens. The lens is substantially coplanar with the frame. Each of a plurality of supports is coupled to and extends between the frame and a base. Each support is extendable wherein an orientation of the lens relative to the base is adjustable. Thus, the supports are configured for focusing light passing through the lens on a selectable location. A solar collector is positioned proximate the lens wherein the lens is configured to focus light on the solar collector.

### BACKGROUND OF THE DISCLOSURE

### Field of the Disclosure

The disclosure relates to energy collection devices and more particularly pertains to a new energy collection device for efficiently focusing and collecting solar energy.

### SUMMARY OF THE DISCLOSURE

An embodiment of the disclosure meets the needs presented above by generally comprising a frame and a lens coupled to the frame such that the frame extends around the lens. The lens is substantially coplanar with the frame. Each of a plurality of supports is coupled to and extends between the frame and a base. Each support is extendable wherein an orientation of the lens relative to the base is adjustable. Thus, the supports are configured for focusing light passing through the lens on a selectable location. A solar collector is positioned proximate the lens wherein the lens is configured to focus light on the solar collector.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF THE DRAWINGS

The disclosure will be better understood and objects other than those set forth above will become apparent when consideration is given to the following detailed description thereof. Such description makes reference to the annexed drawings wherein:

FIG. 1 is a top view of a solar energy collection device according to an embodiment of the disclosure.

FIG. 2 is a side view of an embodiment of the disclosure.

FIG. 3 is a side view of an embodiment of the disclosure.

FIG. 4 is a front view of an embodiment of the disclosure.

FIG. 5 is a side view of an embodiment of the disclosure.

FIG. 6 is a side view of an embodiment of the disclosure.

FIG. 7 is a side view of an embodiment of the disclosure.

### DESCRIPTION OF THE PREFERRED EMBODIMENT

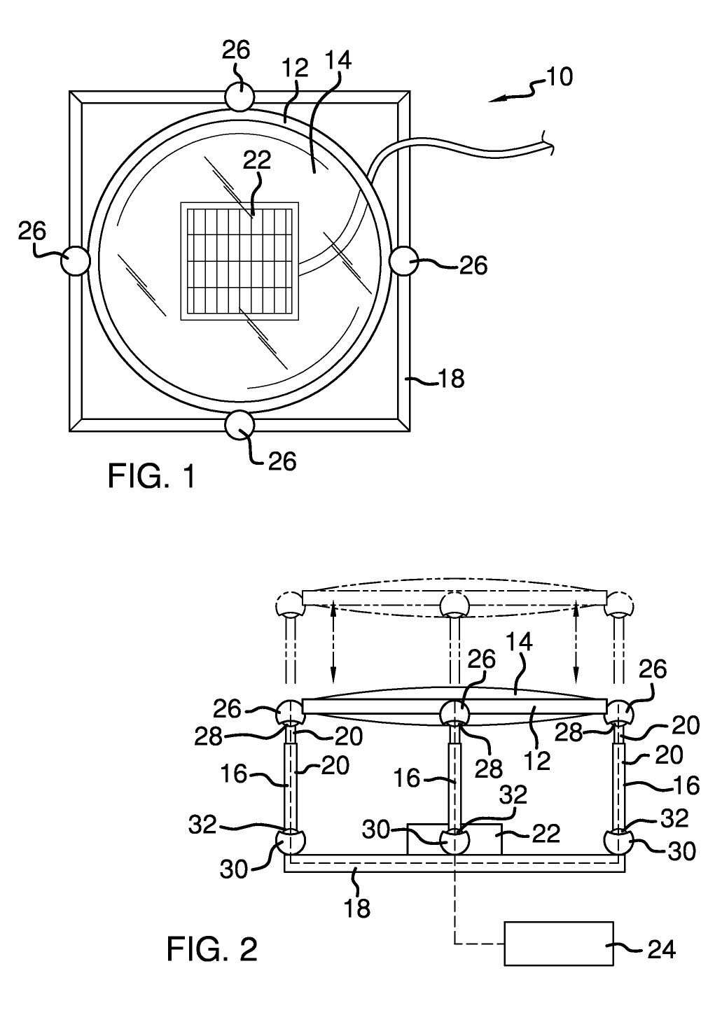

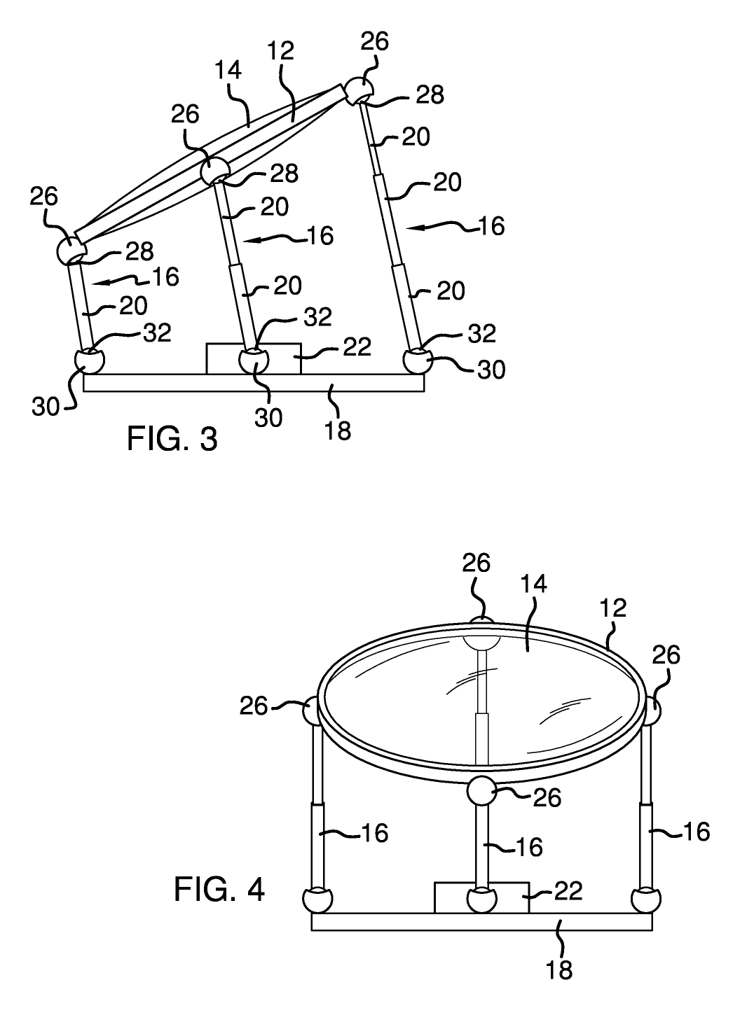

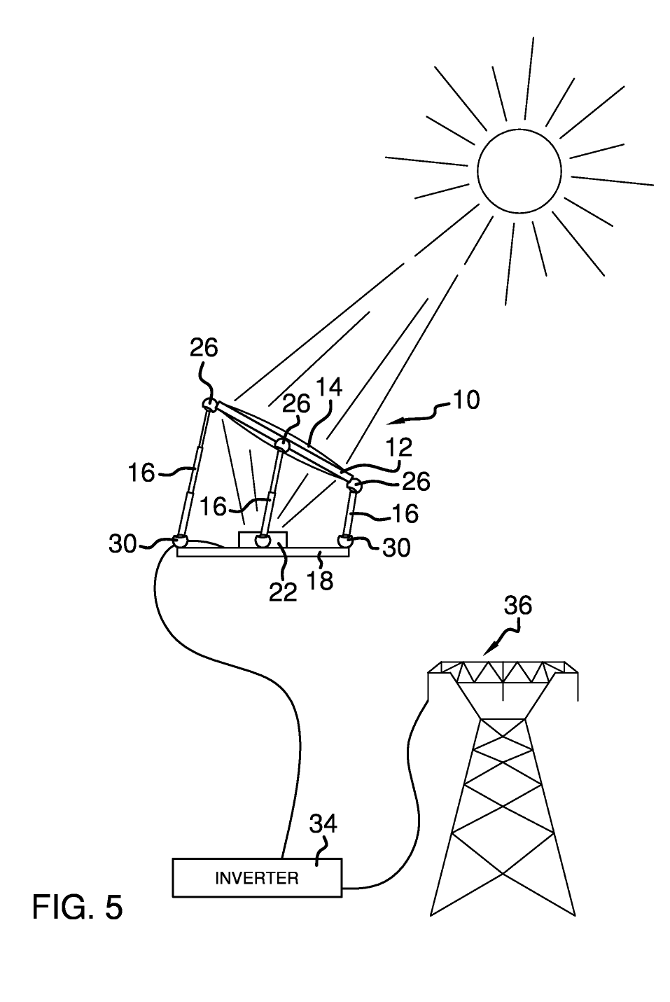

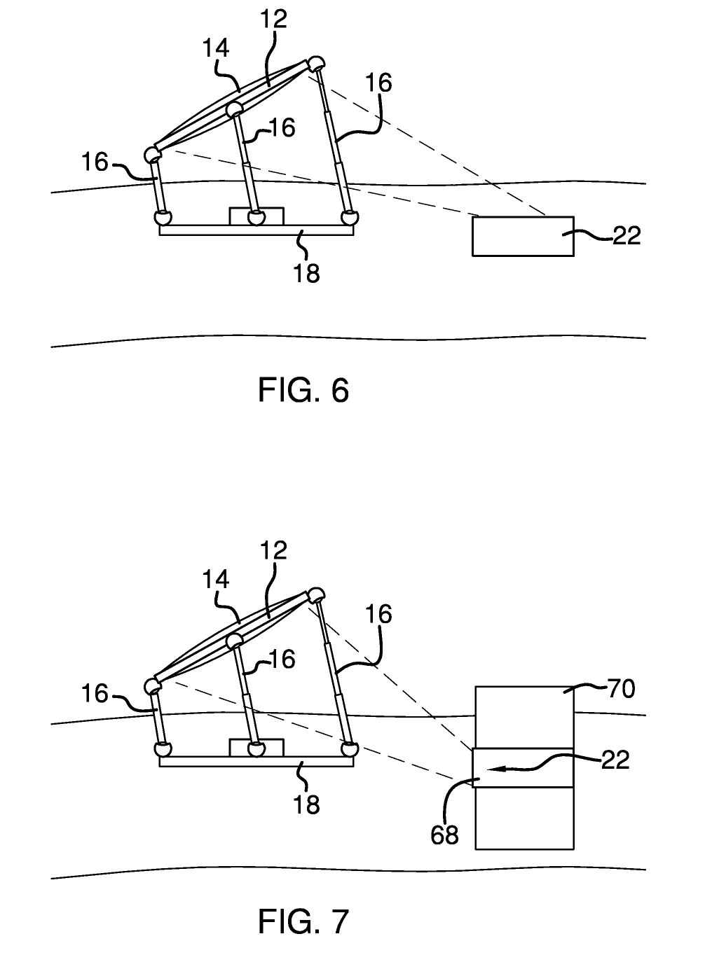

With reference now to the drawings, and in particular to FIGS. 1 through 7 thereof, a new energy collection device embodying the principles and concepts of an embodiment of the disclosure and generally designated by the reference numeral 10 will be described.

As best illustrated in FIGS. 1 through 7, the solar energy collection device 10 generally comprises a frame 12 and a lens 14 coupled to the frame 12 such that the frame 12 extends around the lens 14. The lens 14 may be substantially coplanar with the frame 12 or at least in a positional relationship relative to the frame 12 such that adjustment to positioning of the frame 12 also translates into positioning of the lens 14. The lens 14 is biconvex to focus light passing through the lens 14.

Each of a plurality of supports 16 is coupled to and extends between the frame 12 and a base 18. Each support 16 is elongated and may be formed by a plurality of nested sections 20 which are extendable. Thus, an orientation of the lens 14 relative to the base 18 is adjustable wherein the supports 16 are configured for focusing light passing through the lens 14 on a selectable location. The base 18 may be static or may be positioned on a movable mechanism such as a turntable, platform, or the like. A solar collector 22 is positioned proximate the lens 14 wherein the lens 14 is configured to focus light on the solar collector 22. The solar collector 22 may also be static or movable provided the lens 14 is positionable to maintain focusing light on the solar collector 22.

A processor 24 may be operationally coupled to each support 16 wherein the supports 16 are extended and retracted by the processor 24 such that the lens 14 is positioned to maximize collection and focusing of light on the solar collector 22. When additional components of the overall device 10, such as the frame 12, the base 18, or even the solar collector 22, are not completely static, the processor 24 may be operationally coupled to the systems provided to coordinate adjustment and positioning of the additional components to optimize light directed to the solar collector 22 through the lens 14.

In an embodiment, each of a plurality of upper ball joints 26 couples a respective upper end 28 of an associated one of the supports 16 to the frame 12. The upper ball joints 26 allow the supports 16 to remain in a substantially transverse relationship to the base 18 as the frame 12 is adjusted by extension and retraction of the supports 16. Alternatively, or in combination with the upper ball joints 26, each of a plurality of lower ball joints 30 may couple a respective lower end 32 of an associated one of the supports 16 to the base 18 allowing the supports 16 to remain in a substantially transverse relationship to the frame 12 as the supports 16 are extended and retracted to position the lens 14. Each of the upper ball joints 26 and lower ball joints 30 may be mechanically coupled to the processor and adjusted utilizing conventional mechanical connections.

It is contemplated that the solar collector 22 may be coupled to the base 18 in a substantially central position under the lens 14 for a relatively small application suitable for individual or residential type applications. Alternatively, the solar collector 22 may be positioned in spaced relationship to the base 18. Positioning away from the base 18 allows for greater flexibility and the scale may be enhanced for use in more commercial type applications. In the larger scale type application, the lens 14 may have a diameter between 2 and 4 meters. As shown in FIG. 7, the solar collector 22 may be a band 68 coupled to a tank 70 such as a steam pressure tank. The band 68 is heated by the lens 14.

In use, the lens 14 is periodically or constantly adjusted to optimize focusing of light on the solar collector 22 to maximize production of usable energy from light. The solar collector 22 may be electrically coupled to an inverter 34 and subsequently to a power grid 36 to supplement power production for the power grid 36.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A solar energy collection device comprising:
a frame;
a lens coupled to said frame such that said frame extends around said frame, said lens being substantially coplanar with said frame;
a base;
a plurality of supports, each support being coupled to and extending between said frame and said base, each said support being extendable wherein an orientation of said lens relative to said base is adjustable wherein said supports are configured for focusing light passing through said lens on a selectable location; and
a solar collector positioned proximate said lens wherein said lens is configured to focus light on said solar collector.

2. The device of claim 1, further comprising said solar collector being coupled to said base.

3. The device of claim 1, further comprising said solar collector being positioned in spaced relationship to said base.

4. The device of claim 1, further comprising a processor, said processor being operationally coupled to each said support wherein said supports are extended and retracted by said processor such that said lens is positioned to maximize collection and focusing of light on said solar collector.

5. The device of claim 1, further comprising a plurality of upper ball joints, each of said upper ball joints coupling a respective upper end of an associated one of said supports to said frame.

6. The device of claim 1, further comprising a plurality of lower ball joints, each of said lower ball joints coupling a respective lower end of an associated one of said supports to said base.

7. A solar energy collection device comprising:
a frame;
a lens coupled to said frame such that said frame extends around said frame, said lens being substantially coplanar with said frame;
a base;
a plurality of supports, each support being coupled to and extending between said frame and said base, each said support being extendable wherein an orientation of said lens relative to said base is adjustable wherein said supports are configured for focusing light passing through said lens on a selectable location;
a solar collector positioned proximate said lens wherein said lens is configured to focus light on said solar collector;
a processor, said processor being operationally coupled to each said support wherein said supports are extended and retracted by said processor such that said lens is positioned to maximize collection and focusing of light on said solar collector;
a plurality of upper ball joints, each of said upper ball joints coupling a respective upper end of an associated one of said supports to said frame; and
a plurality of lower ball joints, each of said lower ball joints coupling a respective lower end of an associated one of said supports to said base.

8. The device of claim 7, further comprising said solar collector being coupled to said base.

9. The device of claim 7, further comprising said solar collector being positioned in spaced relationship to said base.
